(19) United States
(12) Patent Application Publication
(10) Pub. No.: US 2011/0230054 A1
(43) Pub. Date: Sep. 22, 2011

(54) SEMICONDUCTOR SUBSTRATE CLEANING METHOD

(76) Inventors: Hiroshi TOMITA, Yokohama-Shi (JP); Hisashi Okuchi, Yokohama-Shi (JP); Minato Inukai, Kawasaki-Shi (JP); Hidekazu Hayashi, Yokohama-Shi (JP); Yasuhito Yoshimizu, Kawasaki-Shi (JP)

(21) Appl. No.: 12/841,217

(22) Filed: Jul. 22, 2010

(30) Foreign Application Priority Data
Mar. 16, 2010 (JP) 2010-59006

(51) Int. Cl. H01L 21/3205; B08B 3/08; B08B 3/12

(52) U.S. Cl. 438/758; 134/30; 134/1.3; 134/28; 257/E21.294

(57) ABSTRACT

In one embodiment, a semiconductor substrate cleaning method is disclosed. The method can clean a semiconductor substrate by using a chemical of 80° C. or above. The method can rinse the semiconductor substrate by using pure water of 40° C. or above after the cleaning of the semiconductor substrate. The method can then rinse the semiconductor substrate by using pure water of 30° C. or below. In addition, the method can dry the semiconductor substrate.

### CROSS REFERENCE TO RELATED APPLICATION

This application is based upon and claims benefit of priority from the Japanese Patent Application No. 2010-59006, filed on Mar. 16, 2010, the entire contents of which are incorporated herein by reference.

### FIELD

Embodiments described herein relate generally to a semiconductor substrate cleaning method.

### BACKGROUND

As the device pattern becomes finer with the advance of the semiconductor manufacturing technique, a cleaning technique capable of removing contaminants such as finer particles from the top of the semiconductor wafer is demanded.

As a conventional cleaning method which aims at removal of particles, ammonia hydrogen peroxide water cleaning (APM cleaning, SC-1 cleaning) of etching an underlying film and lifting off particles is known. In this cleaning method, the underlying film is etched. Therefore, it has become difficult to apply this cleaning method to the manufacturing process of the fine device structure.

Furthermore, as a physical cleaning method, the two-fluid jet cleaning of supplying a fine liquid drop group (drops of water) formed by mixing high-pressure carrier gas and a cleaning liquid to a wafer to remove particles is known. It is known that the particle removal rate is improved if IPA (isopropyl alcohol) is used instead of pure water in the two-fluid jet cleaning (see, for example, Hiroshi Tomita, “Advanced semiconductor wafer cleaning technology,” THE CHEMICAL TIMES, KANTO KAGAKU, 2009, No. 3, pp. 2 to 7).

However, there is a problem that fine particles of 50 nm or less cannot be removed efficiently even if the cleaning method described above is used.

### BRIEF DESCRIPTION OF THE DRAWINGS

FIG. 1 is a schematic configuration diagram of a semiconductor substrate cleaning apparatus according to a first embodiment;

FIG. 2 is a graph showing relations between the substrate temperature and the particle removal rate;

FIG. 3 is a diagram showing a modification of a substrate holding and rotating unit;

FIG. 4 is a diagram showing an example of a cleaning chemical solution;

FIG. 5 is a diagram showing an example of a cleaning chemical solution;

FIG. 6 is a graph showing a quantity of solution of a silicon substrate into warm pure water;

FIG. 7 is a diagram showing the substrate surface after drying in the case where silicate is not removed and in the case where silicate is removed;

FIG. 8 is a flow chart for explaining a semiconductor substrate cleaning method according to the first embodiment;

FIG. 9 is a schematic configuration diagram of a semiconductor substrate cleaning apparatus according to a second embodiment; and

FIG. 10 is a graph showing relations between the underlying film etching quantity and the metal impurity quantity.

### DESCRIPTION OF THE EMBODIMENTS

In one embodiment, a semiconductor substrate cleaning method is disclosed. The method can clean a semiconductor substrate by using a chemical of 80° C. or above. The method can rinse the semiconductor substrate by using pure water of 40° C. or above after the cleaning of the semiconductor substrate. The method can then rinse the semiconductor substrate by using pure water of 30° C. or below. In addition, the method can dry the semiconductor substrate.

Embodiments will now be explained with reference to the accompanying drawings.

### First Embodiment

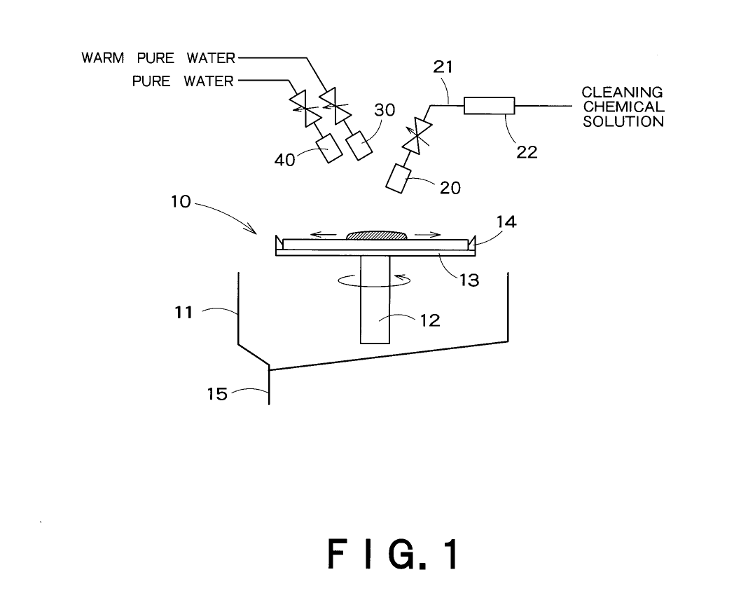

FIG. 1 shows a schematic configuration of a semiconductor substrate cleaning apparatus according to a first embodiment of the present invention. The cleaning apparatus includes a substrate holding and rotating unit 10, a cleaning chemical solution supply unit 20, a warm pure water supply unit 30, and a pure water supply unit 40.

The substrate holding and rotating unit 10 includes a spin cup 11 which forms a processing chamber, a rotation shaft 12, a spin base 13, and a chuck pin 14. The rotation shaft 12 extends nearly in the vertical direction. The spin base 13 which takes a shape of a disk is attached to a top end of the rotation shaft 12. The rotation shaft 12 and the spin base 13 can be rotated by a motor which is not illustrated.

The chuck pin is provided in a fringe part of the spin base 13. Since the chuck pin 14 has the substrate (wafer) W sandwiched between parts thereof, the substrate holding and rotating unit 10 can rotate the substrate W while holding it nearly in the horizontal direction.

If a liquid is supplied from the cleaning chemical solution supply unit 20, the warm pure water supply unit 30, or the pure water supply unit 40 to the vicinity of the rotation center of the surface of the substrate W, the liquid spreads in the radial direction of the substrate W. Extra liquid scattered in the radial direction of the substrate W is captured by the spin cup 11 and exhausted via a waste fluid pipe 15.

The cleaning chemical solution supply unit 20 supplies the cleaning chemical solution to the surface of the substrate W, removes contaminants such as fine particles on the substrate W, and cleans the substrate W. A heater 22 is provided on a chemical solution line 21 of the cleaning chemical solution supply unit 20. The cleaning chemical solution supply unit 20 supplies the chemical solution heated by the heater 22.

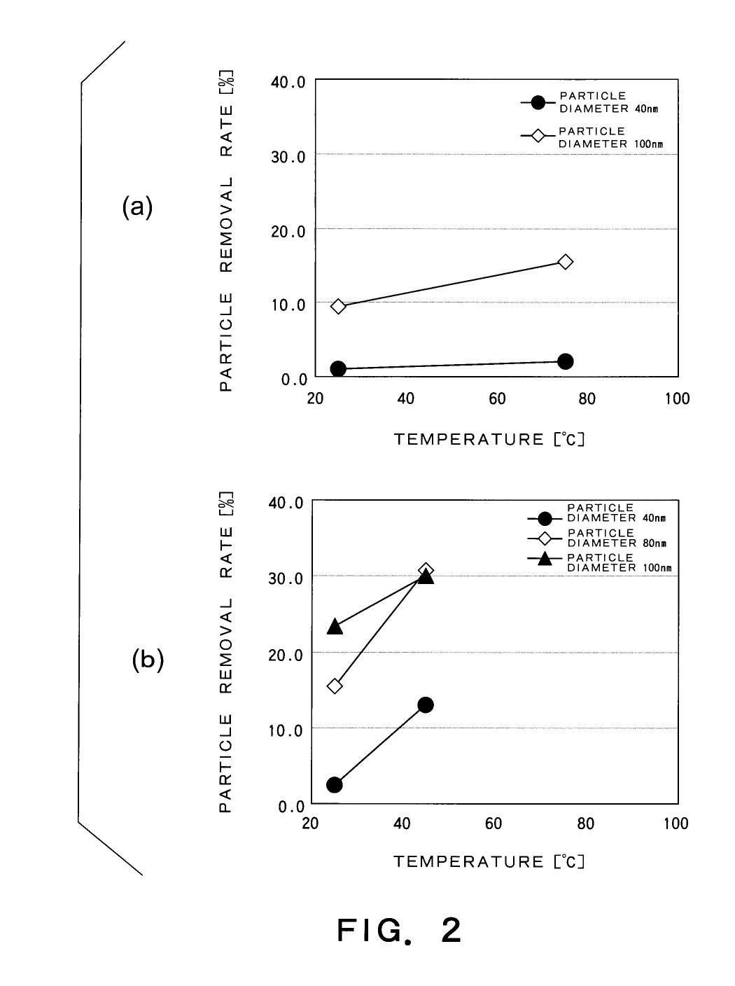

FIG. 2 shows examples of relations between the substrate temperature and the particle removal rate in the case where the two-fluid jet cleaning is conducted. The particles are silicon nitride. Physical energy with which drops of water are applied to the substrate is made the same. FIG. 2(a) shows removal rates of particles which are 40 nm and 100 nm in particle diameter measured when water is used as the cleaning liquid and the substrate temperature is set equal to 25° C. and 75° C. FIG. 2(b) shows removal rates of particles which are 40 nm, 80 nm and 100 nm in particle diameter measured when IPA is used as the cleaning liquid and the substrate temperature is set equal to 25° C. and 45° C.

As appreciated from FIGS. 2(a) and 2(b), the removal rate can be improved by raising the temperature regardless of the particle diameter and no matter which of the cleaning liquids is used. This is considered to be brought about because vibration energy (momentum) of particles is increased by heat. In other words, it is considered to become easier to remove particles by raising the temperature even if physical cleaning is not used.

In the present embodiment, therefore, the substrate cleaning is conducted by using high temperature chemical solution. The IPA used in conventional two-fluid jet cleaning is 82.4° C. in boiling point and high in steam pressure. Therefore, IPA cannot be used at a temperature raised to 80° C. or above. In the present embodiment, a cleaning chemical solution which can be raised in temperature to 80° C. or above is used. It is further desirable that the boiling point of the cleaning chemical solution is higher than that of water.

Furthermore, it is desirable that surface tension of the cleaning chemical solution is lower than that of water. IPA having a concentration of 5% used in the conventional two-fluid jet cleaning has a surface tension of approximately 50 dyn/cm at the room temperature. In the present embodiment, therefore, cleaning chemical solution having a surface tension of 50 dyn/cm or below is used.

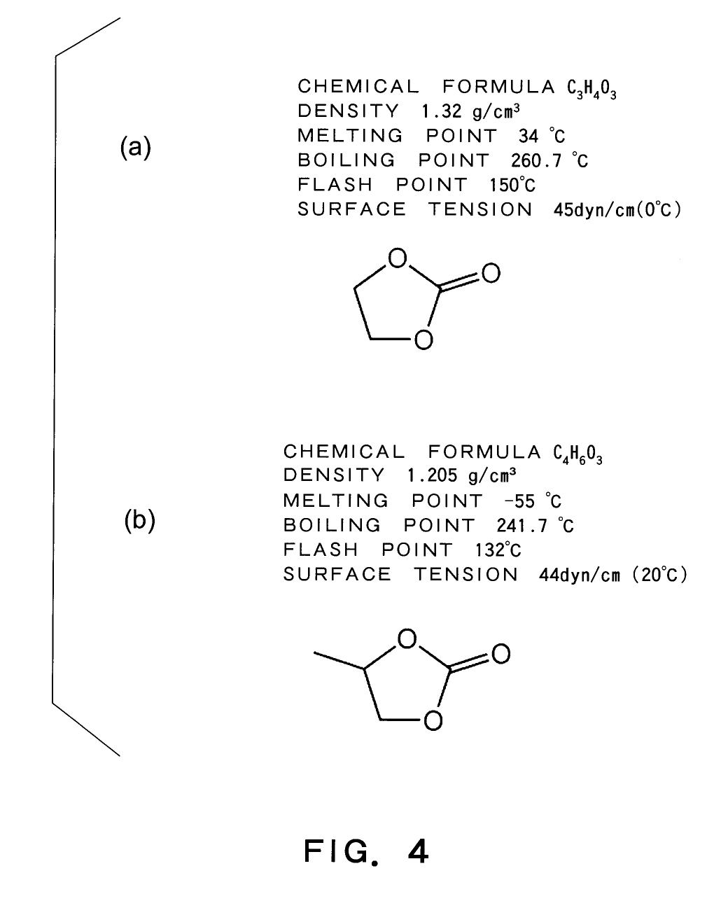

As a cleaning chemical solution which is high in boiling point and low in surface tension, for example, ethylene carbonate shown in FIG. 4(a) or propylene carbonate shown in FIG. 4(b) can be used.

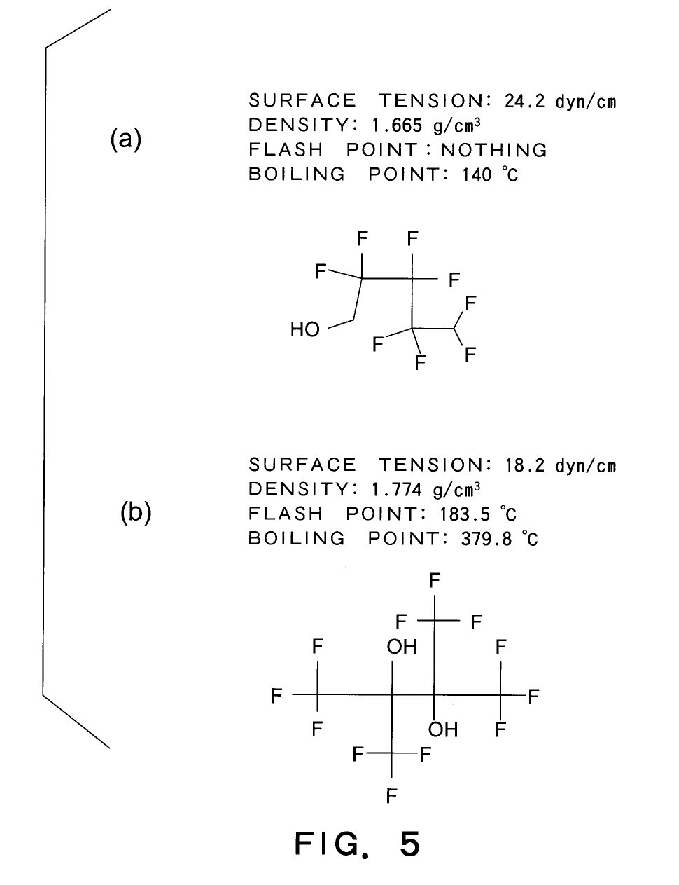

Furthermore, alcohol fluoride shown in FIG. 5(a) and polyhydric alcohol fluoride shown in FIG. 5(b) can also be used as the cleaning chemical solution. Since these chemical solutions are water-soluble, rinse using pure water is possible.

The surface tension of ethylene carbonate is approximately 45 dyn/cm, and the surface tension of propylene carbonate is approximately 44 dyn/cm. The surface tension of alcohol fluoride is far lower than them. On the other hand, the surface tension of water is approximately 60 dyn/cm even if the temperature is raised to 100° C. Therefore, the surface tension of the cleaning chemical solution used in the present embodiment is lower than the surface tension of water at any temperature.

The cleaning chemical solution supply unit 20 provides the cleaning chemical solution with a temperature in the range between 80° C. and the boiling point and supplies the cleaning chemical solution to the surface of the substrate W.

Incidentally, polyhydric alcohol such as ethylene glycol or propylene glycol is also conceivable as a chemical solution which is high in boiling point and low in surface tension. Since these chemical solutions are as low as 111° C. and 99° C., respectively in flash point, however, they are not suitable for use in the semiconductor device manufacturing process.

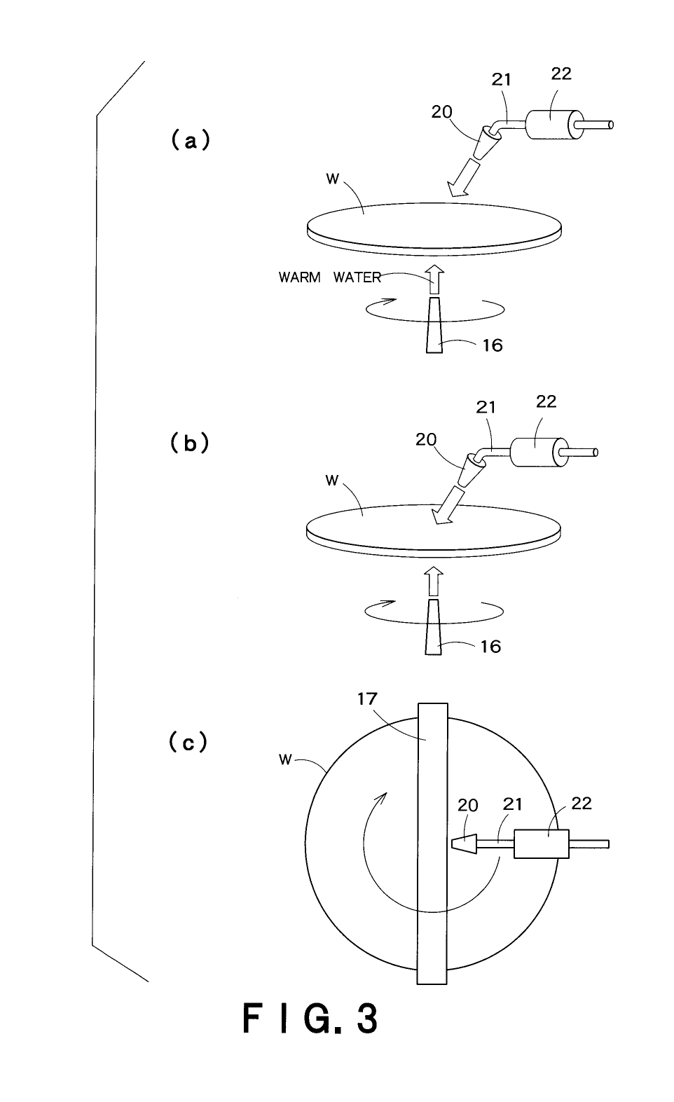

When cleaning the substrate W, the substrate W may be further heated. For example, a water supply unit 16 may be provided on the back side of the substrate W in the substrate holding and rotating unit 10 to supply warm water and increase the temperature of the substrate as shown in FIG. 3(a). As shown in FIGS. 3(b) and (c), an infrared lamp 17 may be provided over the substrate W in the substrate holding and rotating unit 10 to warm the substrate W uniformly. FIG. 3(b) is a side view, and FIG. 3(c) is a top view. The infrared lamp 17 takes a rectilinear shape, and the infrared lamp 17 is provided in parallel to the surface of the substrate W.

After supply of the cleaning chemical solution is stopped, the warm pure water supply unit 30 supplies warm pure water to the surface of the substrate W and rinses the substrate W. The warm pure water supply unit 30 may include a heater to heat pure water at the room temperature and obtain warm pure water.

The warm pure water rinse is conducted to remove the cleaning chemical solution from the top of the substrate W. Since the viscosity of the cleaning chemical solution becomes high as the temperature becomes lower, the cleaning chemical solution is removed by the warm pure water. For example, although the coefficient of viscosity of ethylene carbonate is as small as 1.92 mPa·s at 40° C. and 1.42 mPa·s at 60° C., the viscosity becomes higher as the temperature falls.

The melting point of ethylene carbonate is 34° C. If rinsing is conducted by using pure water of the room temperature, therefore, ethylene carbonate changes from the liquid to the solid and remains on the substrate as particles, resulting in a problem. Solidification of ethylene carbonate can be prevented by rinsing the substrate with warm pure water.

With due regard to this, the warm pure water supply unit 30 supplies warm pure water of 40° C. or above, preferably 60° C. or above to rinse the substrate W.

The pure water supply unit 40 supplies pure water to the surface of the substrate W and rinses the substrate W. The temperature of the pure water supplied by the pure water supply unit 40 is 30° C. or below, and is, for example, nearly the room temperature (22 to 24° C.). The room temperature pure water rinse is conducted after the warm pure water rinse.

The warm pure water supplied by the warm pure water supply unit 30 effectively acts on the rinse out of the cleaning chemical solution. After the rinse out of the cleaning chemical solution, oxygen gas dissolved in the warm pure water acts upon the silicon substrate or the polysilicon film, and the silicon substrate or the polysilicon film is slightly etched, and silicate is formed in the warm pure water.

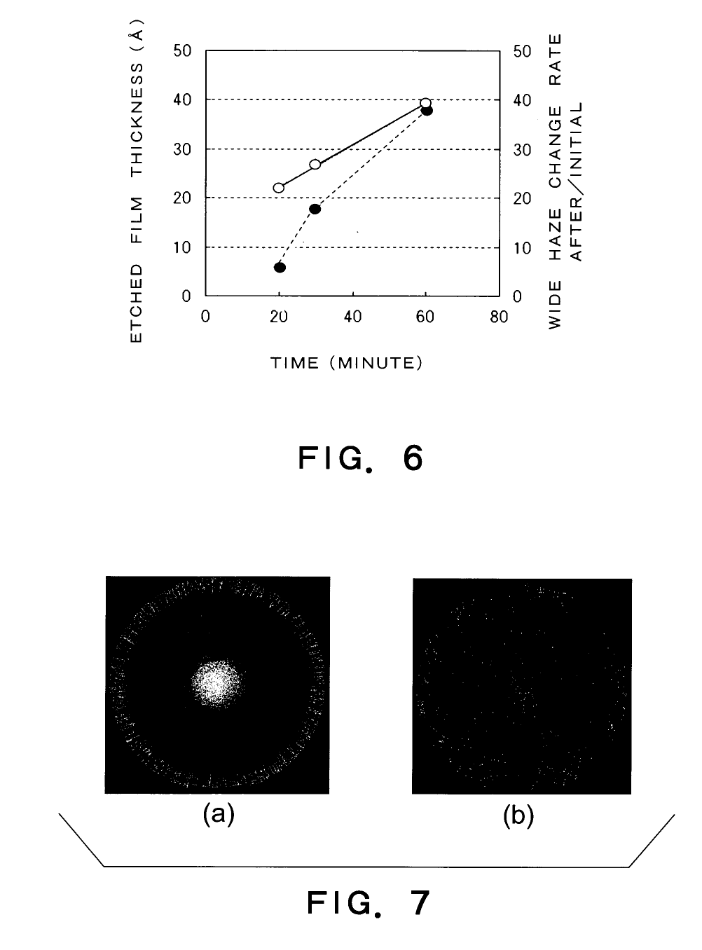

FIG. 6 shows a quantity of solution of a silicon substrate into the warm pure water. Here, the etching rate of the film is calculated by using a polysilicon film in order to quantitatively find the etching quantity of silicon in the warm pure water. After diluted hydrofluoric acid treatment is conducted and a natural oxide film formed on the polysilicon film is removed, the initial polysilicon film thickness is measured. Then, warm pure water rinse treatment at 65° C. is conducted 20 minutes after, 30 minutes after, and 60 minutes after. Then, the room temperature pure water rinse treatment is conducted for 10 minutes each time. Then, the polysilicon film is dried, and the polysilicon film thickness after the warm pure water rinse treatment is measured. The etched film thickness of the polysilicon film is measured. Furthermore, the silicon substrate is processed concurrently with processing of the substrate having the polysilicon film, and a change of silicon substrate face roughness (haze) is also measured. In graphs shown in FIG. 6, a solid line indicates the etching film thickness and a dashed line indicates a change rate of the silicon substrate face (haze).

The etching rate of polysilicon in a time period between 20 minutes after and 30 minutes after is approximately 0.49 Å/minute, and the etching rate of polysilicon in a time period between 30 minutes after and 60 minutes after is approximately 0.41 Å/minute. Therefore, it is appreciated that the warm pure water rinse treatment at 65° C. causes polysilicon etching in the range of approximately 0.4 to 0.5 Å/minute. Furthermore, it is appreciated from the measurement result of the silicon substrate face roughness as well that the face haze increases as the treatment (processing) time of the warm pure water rinse treatment increases.

It is appreciated that the silicon substrate is etched by warm pure water.

There is a problem that watermark defects occur in a center part and a peripheral part as shown in FIG. 7(a) if spin drying is conducted on the substrate without removing silicate. Occurrence of watermark defects can be prevented as shown in FIG. 7(b) by conducting the warm pure water rinse, conducting the room temperature pure water rinse to remove silicate, and then conducting spin drying. In the room temperature pure water rinse, the silicon substrate is little etched.

It is known that the quantity of silicon dissolved from the silicon substrate into pure water is great especially in the n+ substrate and the p-substrate. If the substrate W which becomes an object of cleaning treatment is a substrate with an n+ diffusion layer area or a p-diffusion layer area formed on a part or the whole of the substrate surface, the effect of preventing occurrence of watermark defects by conducting the room temperature pure water rinse after the warm pure water rinse is especially great.

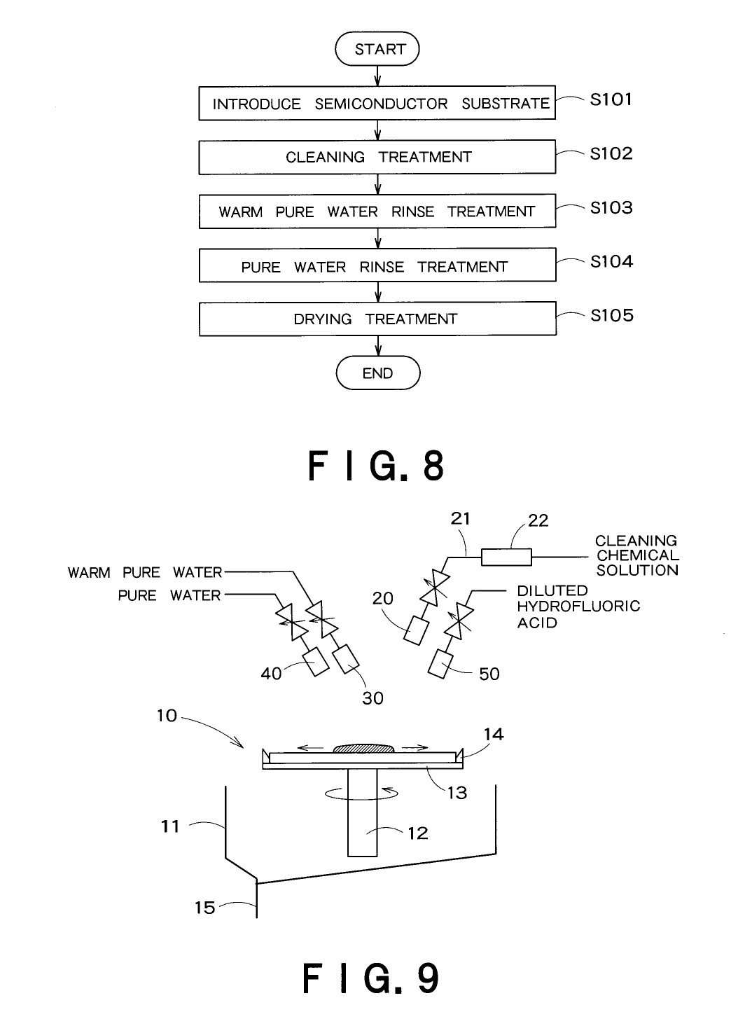

A substrate cleaning method using such a cleaning apparatus will now be described with reference to a flow chart shown in FIG. 8.

(Step S101) The semiconductor substrate W is carried by a transportation unit (not illustrated), and held by the substrate holding and rotating unit 10. A convex shape pattern such as a line and space pattern may be formed on the semiconductor substrate W. Furthermore, at least a part of the convex shape pattern may be formed of a film containing silicon. The convex shape pattern is formed according to, for example, the RIE (Reactive Ion Etching) method or the like.

(Step S102) The semiconductor substrate W is rotated at a predetermined rotation speed, and the cleaning chemical solution from the cleaning chemical solution supply unit 20 is supplied to the vicinity of the rotation center of the surface of the semiconductor substrate W. The cleaning chemical solution is ethylene carbonate of a high temperature, for example, 80° C. or above. If the cleaning apparatus includes a mechanism for warming the substrate W, the substrate W may be warmed.

The cleaning chemical solution is extended over the whole area of the surface of the semiconductor substrate W by centrifugal force which is caused by rotation of the semiconductor substrate W, and particle removal (cleaning) treatment of the semiconductor substrate W is conducted. Since the high temperature cleaning chemical solution is used, fine particles can also be removed effectively.

(Step S103) Warm pure water of 40° C. or above, preferably 60° C. or above from the warm pure water supply unit 30 is supplied to the vicinity of the rotation center of the surface of the semiconductor substrate W. The warm pure water is extended over the whole area of the surface of the semiconductor substrate W by centrifugal force which is caused by rotation of the semiconductor substrate W. As a result, warm pure water rinse treatment is conducted to rinse the cleaning chemical solution which remains on the surface of the semiconductor substrate W by using warm pure water. Since high temperature warm pure water is used, the viscosity of the cleaning chemical solution can be held down to a low value and the cleaning chemical solution can be easily removed from the top of the substrate.

At this time, it is possible that fine etching of the silicon substrate or the polysilicon film occurs and silicate is formed in the warm pure water by the etching.

(Step S104) Pure water of the room temperature from the pure water supply unit 40 is supplied to the vicinity of the rotation center of the surface of the semiconductor substrate W. The pure water of the room temperature is extended over the whole area of the surface of the semiconductor substrate W by centrifugal force which is caused by rotation of the semiconductor substrate W. As a result, pure water rinse treatment is conducted to remove the silicate formed in the warm pure water at step S103.

(Step S105) Dry treatment of the semiconductor substrate W is conducted. For example, spin dry treatment is conducted by raising the rotation speed of the semiconductor substrate W to a predetermined spin dry rotation speed and shaking off pure water which remains on the surface of the semiconductor substrate W to dry it. Since fine particles are removed at step S102 and the silicate is removed at step S104, the substrate surface can be brought into an extremely clean state.

According to the present embodiment, fine particles can be removed efficiently in this way. Furthermore, since cleaning treatment is conducted at a high temperature of 80° C. or above, fine particles are removed by only vibration energy which is brought about by heat. Therefore, damages on the pattern formed on the substrate can be reduced remarkably as compared with the physical cleaning method such as the two-fluid jet cleaning.

### Second Embodiment

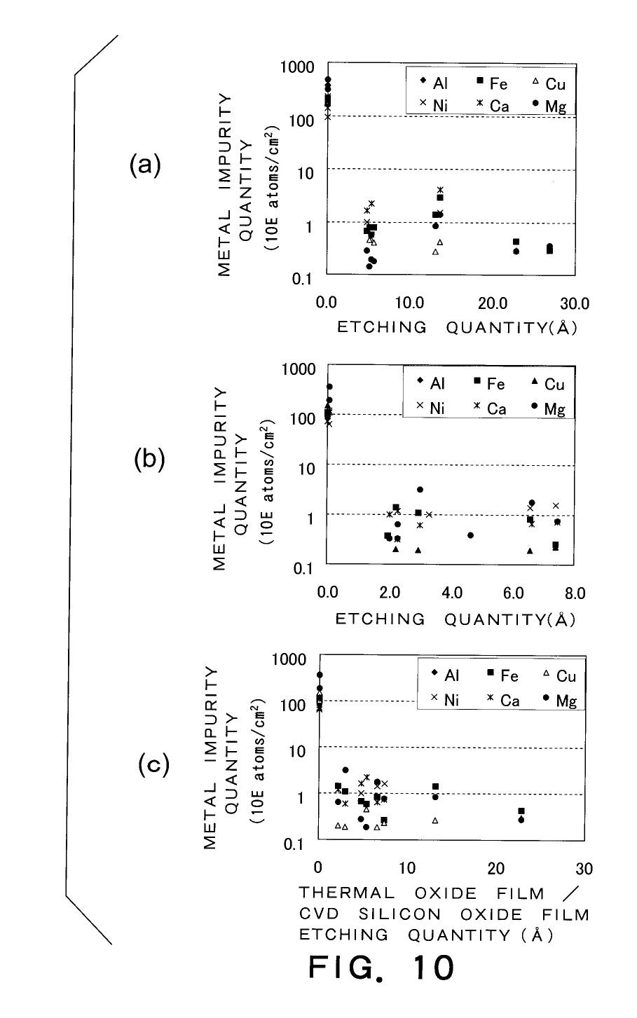

FIG. 9 is a schematic configuration diagram of a semiconductor substrate cleaning apparatus according to a second embodiment of the present invention. The cleaning apparatus according to the present embodiment has a configuration obtained by adding a diluted hydrofluoric acid supply unit 50 to the cleaning apparatus according to the first embodiment shown in FIG. 1.

The diluted hydrofluoric acid supply unit 50 supplies diluted hydrofluoric acid to the surface of the substrate W and removes metal impurities on the substrate W. FIG. 10 shows relations between the underlying film etching quantity and the metal impurity quantity on the substrate obtained by conducting diluted hydrofluoric acid treatment. FIG. 10(a) shows the relations in the case where the underlying film is a silicon oxide film (CVD silicon oxide film) formed by using the CVD (Chemical Vapor Deposition) method, and FIG. 10(b) shows the relations in the case where the underlying film is a silicon oxide film (thermal oxide film) formed by using the thermal oxidation. As appreciated from FIGS. 10(a) and (b), the metal removal rate is improved as the etching quantity of the underlying film increases.

FIG. 10(c) shows a normalized metal impurity quantity as the underlying silicon oxide film etching quantity. It is appreciated from FIG. 10(c) that the metal impurities can be almost removed regardless of the kind of the underlying film by simply conducting etching of approximately 2 Å (0.2 nm).

Therefore, it is appreciated that metal impurities can be removed by the diluted hydrofluoric acid treatment even if the process (such as SC-2 or SPM) used in the conventional metal removal is not used.

In the present embodiment, the diluted hydrofluoric acid treatment (cleaning treatment using a chemical solution containing diluted hydrofluoric acid) is added to the cleaning method according to the first embodiment to remove metal impurities. The diluted hydrofluoric acid treatment can be conducted before the particle removal (i.e., between steps S101 and S102 in the flow chart shown in FIG. 8). In this case, room temperature pure water rinse treatment is further conducted after the diluted hydrofluoric acid treatment.

Furthermore, the diluted hydrofluoric acid treatment may be conducted after the room temperature pure water rinse treatment (i.e., between steps S104 and S105 in the flow chart shown in FIG. 8). In this case as well, room temperature pure water rinse treatment is conducted after the diluted hydrofluoric acid treatment.

According to the present embodiment, not only fine particles are removed efficiently but also metal impurities can be removed in this way.

Although metal impurities are removed by using diluted hydrofluoric acid in the second embodiment, a chemical solution containing any one of hydrochloric acid, sulfuric acid, hydrogen peroxide water, and ozone water may also be used.

Although an example using a single-wafer cleaning apparatus has been described in the embodiment, similar cleaning can be conducted even by using a batch-wafer cleaning apparatus.

Furthermore, an ultrasonic vibrator may be provided in the cleaning apparatus according to the embodiment to apply an ultrasonic wave when cleaning the substrate.

In the cleaning apparatus according to the embodiment, the cleaning chemical solution may be circulated to remove particles in the cleaning chemical solution by using a filter and reuse the cleaning chemical solution. As a result, the cleaning chemical solution can be used for a long term and the cost can be reduced.

The embodiment has been described by taking the case where a pattern is formed on the surface of the substrate of the cleaning object as an example. However, the surface of the substrate may be in any state, and, for example, the surface of the substrate may be flat. Furthermore, the substrate of cleaning object may be a substrate other than a semiconductor substrate, such as a glass substrate in a liquid crystal display apparatus.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and sprit of the invention.

What is claimed is:

1. A semiconductor substrate cleaning method comprising:
cleaning a semiconductor substrate by using a chemical solution of 80° C. or above;
rinsing the semiconductor substrate by using pure water of 40° C. or above, after the cleaning of the semiconductor substrate;
rinsing the semiconductor substrate by using pure water of 30° C. or below, after the rinsing of the semiconductor substrate using the pure water of 40° C. or above; and
drying the semiconductor substrate, after the rinsing of the semiconductor substrate using the pure water of 30° C. or below.

2. The semiconductor substrate cleaning method according to claim 1, comprising rinsing the semiconductor substrate by using pure water of 60° C. or above, after the cleaning of the semiconductor substrate.

3. The semiconductor substrate cleaning method according to claim 1, wherein an n+ diffusion layer area or a p-diffusion layer is formed on at least a part of surface of the semiconductor substrate.

4. The semiconductor substrate cleaning method according to claim 1, wherein an ultrasonic wave is applied to the semiconductor substrate when cleaning the semiconductor substrate.

5. The semiconductor substrate cleaning method according to claim 1, wherein the chemical solution includes any one of ethylene carbonate, propylene carbonate, alcohol fluoride, and polyhydric alcohol fluoride.

6. The semiconductor substrate cleaning method according to claim 1, further comprising, before the cleaning of the semiconductor substrate using the chemical solution,
cleaning the semiconductor substrate by using diluted hydrofluoric acid; and
rinsing the semiconductor substrate by using pure water of 30° C. or below, after the cleaning of the semiconductor substrate using diluted hydrofluoric acid.

7. The semiconductor substrate cleaning method according to claim 6, comprising, after the cleaning of the semiconductor substrate using the chemical solution, rinsing the semiconductor substrate by using pure water of 60° C. or above.

8. The semiconductor substrate cleaning method according to claim 6, wherein an n+ diffusion layer area or a p-diffusion layer is formed on at least a part of surface of the semiconductor substrate.

9. The semiconductor substrate cleaning method according to claim 6, wherein an ultrasonic wave is applied to the semiconductor substrate when cleaning the semiconductor substrate.

10. The semiconductor substrate cleaning method according to claim 6, wherein the chemical solution includes any one of ethylene carbonate, propylene carbonate, alcohol fluoride, and polyhydric alcohol fluoride.

11. The semiconductor substrate cleaning method according to claim 1, comprising, before drying the semiconductor substrate after the rinsing of the semiconductor substrate using the pure water of 30° C. or below,
cleaning the semiconductor substrate by using diluted hydrofluoric acid; and
rinsing the semiconductor substrate by using pure water of 30° C. or below, after the cleaning of the semiconductor substrate using diluted hydrofluoric acid.

12. The semiconductor substrate cleaning method according to claim 11, comprising, after the cleaning of the semiconductor substrate using the chemical solution, rinsing the semiconductor substrate by using pure water of 60° C. or above.

13. The semiconductor substrate cleaning method according to claim 11, wherein an n+ diffusion layer area or a p-diffusion layer is formed on at least a part of surface of the semiconductor substrate.

14. The semiconductor substrate cleaning method according to claim 11, wherein an ultrasonic wave is applied to the semiconductor substrate when cleaning the semiconductor substrate.

15. The semiconductor substrate cleaning method according to claim 11, wherein the chemical solution includes any one of ethylene carbonate, propylene carbonate, alcohol fluoride, and polyhydric alcohol fluoride.
